(19) United States
(12) Patent Application Publication
(10) Pub. No.: US 2026/0114280 A1
(43) Pub. Date: Apr. 23, 2026

(54) MEMORY DEVICE

(71) Applicant: SAMSUNG ELECTRONICS CO., LTD., Suwon-si (KR)

(72) Inventors: Sang Ho PARK, Suwon-si (KR); Ji Yong KIM, Suwon-si (KR)

(73) Assignee: SAMSUNG ELECTRONICS CO., LTD., Suwon-si (KR)

(21) Appl. No.: 19/294,850

(22) Filed: Aug. 8, 2025

(30) Foreign Application Priority Data
Oct. 21, 2024 (KR) 10-2024-0143870

(51) Int. Cl. H01L 23/40; H01L 23/00; H01L 23/053; H01L 23/10; H01L 23/60; H01L 25/065; H01L 25/10; H10B 80/00

(52) U.S. Cl. CPC H10W 40/641; H10W 40/613; H10W 42/60; H10W 76/15; H10W 76/60; H10W 90/00; H10B 80/00; H10W 40/233; H10W 40/60; H10W 40/611; H10W 90/22; H10W 90/288; H10W 90/291; H10W 90/734; H10W 90/736

(57) ABSTRACT

A memory device includes a first case, a second case coupled to the first case, a mid plate placed in an inner space between the first and second cases, a first memory module between the first case and the mid plate, including a first module substrate and at least one first electronic chip on the first module substrate, and a second memory module between the second case and the mid plate, including a second module substrate and at least one second electronic chip on the second module substrate, wherein the mid plate includes a base unit, a first rib structure extending from the base unit to electrically connect the mid plate to the first module substrate, and a second rib structure spaced apart from the first rib structure to electrically connect the mid plate to the first module substrate.

### CROSS-REFERENCE TO RELATED APPLICATION

This application is based on and claims priority from Korean Patent Application No. 10-2024-0143870, filed on Oct. 21, 2024, in the Korean Intellectual Property Office and all the benefits accruing therefrom under 35 U.S.C. 119, the disclosure of which is herein incorporated by reference in its entirety.

### BACKGROUND

### 1. Field

One or more example embodiments of the disclosure relate to a memory device.

### 2. Description of Related Art

A solid state drive (SSD) device enables input and output of a large amount of data at high speed when the SSD device is used as a storage device, and a demand for the SSD device is increasing. The SSD device is generally provided in a form of a package in which memory chips are packaged on a printed circuit board (PCB). As a data processing speed of the SSD device increases, the SSD device requires a method for preventing noise caused by external electromagnetic interference and electrostatic discharge (ESD). In addition, with the miniaturization and high performance of the SSD device, the SSD device having high heat dissipation characteristics is desirable.

### SUMMARY

One or more example embodiments of the disclosure provide a memory device with improved reliability.

The objects of the disclosure are not limited to those mentioned above and additional objects of the disclosure, which are not mentioned herein, will be clearly understood by those skilled in the art from the following description of the disclosure.

According to an aspect of an example embodiment of the disclosure, there is provided a memory device including a first case; a second case coupled to the first case; a mid plate in an inner space between the first case and the second case, the mid plate extending in a first direction; a first memory module between the first case and the mid plate, the first memory module including a first module substrate and at least one first electronic chip on the first module substrate; and a second memory module between the second case and the mid plate, the second memory module including a second module substrate and at least one second electronic chip on the second module substrate, wherein the mid plate includes a base unit extending in the first direction, a first rib structure extending from the base unit in a second direction crossing the first direction to electrically connect the mid plate to the first module substrate, and a second rib structure spaced apart from the first rib structure in the first direction and extending in the second direction to electrically connect the mid plate to the first module substrate.

According to an aspect of an example embodiment of the disclosure, there is provided a memory device including: a first case; a second case coupled to the first case; a mid plate in an inner space between the first case and the second case, the mid plate extending in a first direction; a first memory module between the first case and the mid plate, the first memory module including a first module substrate and at least one first electronic chip on the first module substrate; and a second memory module between the second case and the mid plate, the second memory module including a second module substrate and at least one second electronic chip on the second module substrate, wherein the mid plate includes a base unit and a first rib structure on the base unit, surrounding the at least one first electronic chip and electrically connecting the mid plate to the first module substrate.

According to an aspect of an example embodiment of the disclosure, there is provided a memory device including: a first case; a second case coupled to the first case; a mid plate in an inner space between the first case and the second case, the mid plate extending in a first direction; a first module substrate between the first case and the mid plate, the first module substrate including a first surface facing the first case and a second surface facing the mid plate; at least one first electronic chip on the first surface of the first module substrate; at least one second electronic chip on the second surface of the first module substrate; a second module substrate between the second case and the mid plate, the second module substrate including a third surface facing the second case and a fourth surface facing the mid plate; at least one third electronic chip on the third surface of the second module substrate; and at least one fourth electronic chip on the fourth surface of the second module substrate, wherein the mid plate includes a base unit, a first rib structure on the base unit, surrounding the at least one first electronic chip and electrically connecting the mid plate to the second surface of the first module substrate, and a second rib structure on the base unit, surrounding the at least one fourth electronic chip and electrically connecting the mid plate to the fourth surface of the second module substrate.

### BRIEF DESCRIPTION OF DRAWINGS

The above and other aspects and features of the disclosure will become more apparent by describing in detail example embodiments thereof with reference to the attached drawings.

FIG. 1 is an exploded perspective view of a memory device according to one or more embodiments of the disclosure.

FIG. 2 is a perspective view of a memory device according to one or more embodiments of the disclosure.

FIG. 3 is a cross-sectional view taken along line A-A′ of FIG. 2.

FIGS. 4 and 5 are examples of cross-sectional views taken along line B-B′ of FIG. 3.

FIG. 6 is a cross-sectional view taken along line C-C′ of FIG. 3.

FIG. 7 is a cross-sectional view taken along line D-D′ of FIG. 3.

FIG. 8 is a cross-sectional view taken along line E-E′ of FIG. 3.

FIG. 9 is a cross-sectional view taken along line F-F′ of FIG. 2.

FIG. 10 is a partial perspective view illustrating a hook included in a memory device according to one or more embodiments of the disclosure.

FIG. 11 is an enlarged view of a region P of FIG. 9.

FIG. 12 is a cross-sectional view illustrating a first modified example of the hook shown in FIG. 11.

FIG. 13 is a perspective view illustrating a second modified example of the hook shown in FIG. 11.

FIG. 14 is a perspective view illustrating a coupling relationship between a mid plate and the second modified example of the hook shown in FIG. 13.

FIG. 15 is an exploded perspective view of a memory device according to one or more embodiments of the disclosure.

FIG. 16 is a perspective view of a memory device according to one or more embodiments of the disclosure.

FIG. 17 is a cross-sectional view taken along line G-G′ of FIG. 15.

FIG. 18 is a schematic view of a memory device according to one or more embodiments of the disclosure.

FIG. 19 is a block diagram of a system including a memory device according to one or more embodiments of the disclosure.

### DETAILED DESCRIPTION

Hereinafter, example embodiments of the disclosure will be described clearly and in detail to an extent that a person skilled in the art may easily practice the disclosure using the attached drawings.

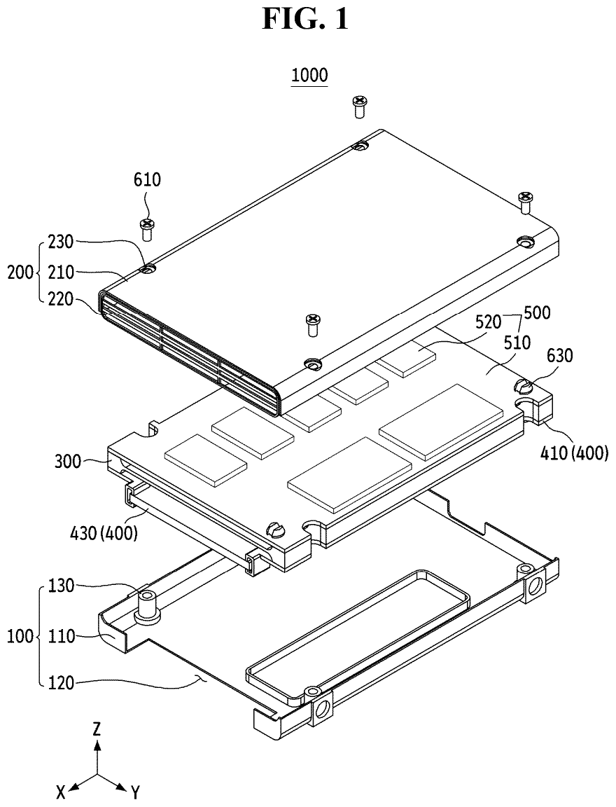

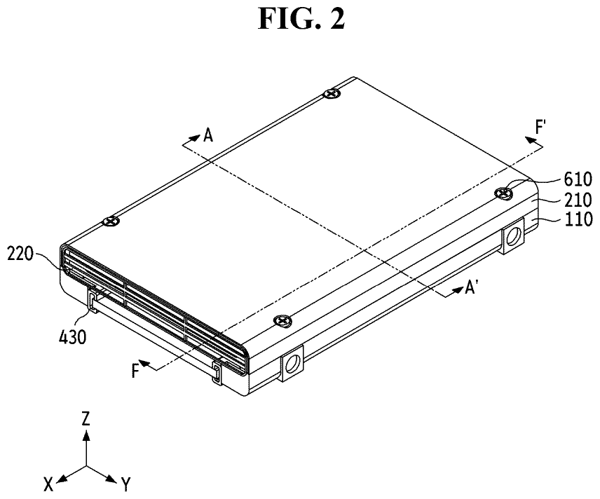

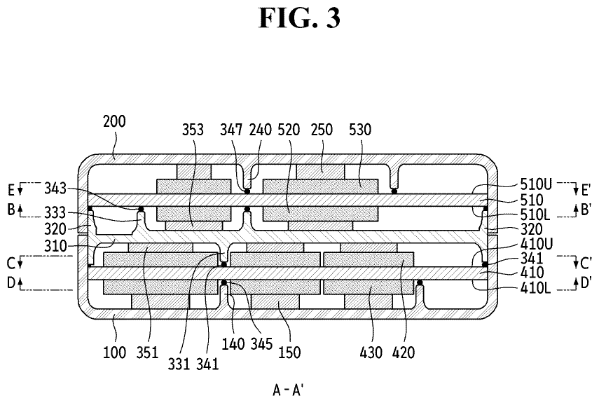

FIG. 1 is an exploded perspective view of a memory device according to one or more embodiments of the disclosure. FIG. 2 is a perspective view of a memory device according to one or more embodiments of the disclosure. FIG. 3 is a cross-sectional view taken along line A-A′ of FIG. 2.

Referring to FIG. 1, a memory device 1000 includes a case, a mid plate 300, a first memory module 400, a second memory module 500, a screw 610, and a hook 630.

The case may provide an external appearance of the memory device 1000. The case may have a three-dimensional shape that includes an accommodation space in which various components are accommodated. For example, the case may include a lower and side wall 110 and an upper and side wall 210. The lower and side wall 110 may include a lower wall having a flat plate shape, and the upper and side wall 210 may include an upper wall having a flat plate shape, and the lower and side wall 110 and the upper and side wall 210 include a sidewall extending between the lower wall and the upper wall, respectively.

The lower wall of the lower and side wall 110 and the upper wall of the upper and side wall 210 of the case may have a shape of a flat plate that extends in a first direction X (e.g., X-axis direction) and a second direction Y (e.g., Y-axis direction). The sidewalls of the lower and side wall 110 and the upper and side wall 210 extend between the lower wall of the lower and side wall 110 and the upper wall of the upper and side wall 210 of the case and may have a shape extending in a third direction Z (e.g., Z-axis direction). In one or more embodiments, the case may have a hexahedral shape. However, the shape of the case is not limited to those illustrated above, and the case may have any other shapes, for example, a polygonal column shape such as a pentagonal column and a hexagonal column, or a circular column (or cylinder) shape.

The case may include a first case 100 and a second case 200 detachably coupled to each other. The first case 100 may be coupled to the second case 200 to provide an accommodation space defined by (or between) the first case 100 and the second case 200.

The first case 100 may include the lower and side wall 110, a first hole 120, and a first screw hole 130.

The lower and side wall 110 of the first case 100 may include a first rib unit (or first rib structure) 140 in which a portion of the lower and side wall 110 extends in the third direction Z. The first hole 120 may be a space in which an external connector is to be positioned. The first screw hole 130 may be a hole into which the screw 610 for fixing the memory device 1000 is to be inserted.

The second case 200 may include the upper and side wall 210, a vent hole 220, and a second screw hole 230.

The upper and side wall 210 of the second case 200 may include a second rib unit (or second rib structure) 240 in which a portion of the upper and side wall 210 extends in the third direction Z. The vent hole 220 may be a path through which external air passes through the accommodation space in the memory device 1000. Heat in the case may be discharged through the vent hole 220. The second screw hole 230 may be a hole into which the screw 610 for fixing the memory device 1000 is to be inserted. The second screw hole 230 may overlap the first screw hole 130 in the third direction Z.

The case may include a material having high thermal conductivity so as to be suitable for discharging heat generated in components disposed in the case, for example, first to fourth electronic chips 420, 430, 520 and 530 to an outside of the case. For example, thermal conductivity of the case may be at least 10 [W/(mK)] or more. The case may include a single material or a combination of different materials. The case may include metal, a carbon-based material, a polymer, or any combination thereof. The case may include, for example, copper (Cu), aluminum (Al), zinc (Zn), tin (Sn), stainless steel, or a clad metal containing these materials. Alternatively, the case may include, for example, graphite, graphene, carbon fiber, a carbon nanotube composite, and the like. Alternatively, the case may include, for example, epoxy resins, polymethylmethacrylate (PMMA), polycarbonate (PC), polyethylene (PE), polypropylene (PP), and the like.

The mid plate 300 may be positioned inside the case. The mid plate 300 may be positioned in the accommodation space of the case. The mid plate 300 may include a base unit 310, a connection unit 320, a third rib unit (or third rib structure) 331, and a fourth rib unit (or fourth rib structure) 333.

In detail, the base unit 310 may have a flat plate shape extending in the first direction X and the second direction Y. In one or more embodiments, the base unit 310 may overlap the upper and side wall 210 and the lower and side wall 110 of the case in the third direction Z.

The connection unit 320 may extend from the base unit 310 in the third direction Z. In one or more embodiments, the connection unit 320 may be connected to a portion of the first memory module 400 or a portion of the second memory module 500.

In one or more embodiments, a first conductive gasket 341 may be positioned between the connection unit 320 and the first memory module 400. A second conductive gasket 343 may be positioned between the connection unit 320 and the second memory module 500. The first conductive gasket 341 may enhance bonding between the connection unit 320 and the first memory module 400. The second conductive gasket 343 may enhance bonding between the connection unit 320 and the second memory module 500.

The third rib unit 331 and the fourth rib unit 333 may extend from the base unit 310 in the third direction Z. For example, the third rib unit 331 may extend from the base unit 310 toward the first memory module 400. The fourth rib unit 333 may extend from the base unit 310 toward the second memory module 500.

The first conductive gasket 341 may be positioned between the third rib unit 331 and a first module substrate 410. The first conductive gasket 341 may enhance bonding between the third rib unit 331 and the first module substrate 410. The third rib unit 331 may be electrically connected to the first module substrate 410 by the first conductive gasket 341.

The second conductive gasket 343 may be positioned between the fourth rib unit 333 and a second module substrate 510. The second conductive gasket 343 may enhance bonding between the fourth rib unit 333 and the second module substrate 510. The fourth rib unit 333 may be electrically connected to the second module substrate 510 by the second conductive gasket 343.

The first and second conductive gaskets 341 and 343 may be copper films or soldering clips. The conductive gaskets are only one of examples the disclosure may include, in addition to or alternatively to the conductive gaskets, various materials having conductivity and/or adhesiveness.

The first to fourth rib units 140, 240, 331 and 333 may make physical and/or electrical contact with the first module substrate 410, the second module substrate 510, and/or the mid plate 300 without physical damage through the first and second conductive gaskets 341 and 343, and a third conductive gasket 345 and a fourth conductive gasket 347, respectively. Accordingly, structural reliability of the first to fourth rib units 140, 240, 331 and 333 may be improved, and reliability of electrostatic discharge (ESD) shielding performance using the first to fourth rib units 140, 240, 331, and 333 may be improved.

The third rib unit 331 of the mid plate 300 may be connected to a ground line (not shown) of the first module substrate 410. The fourth rib unit 333 of the mid plate 300 may be connected to a ground line (not shown) of the second module substrate 510. The mid plate 300 may be a conductive material connected to the ground line to prevent noise caused by electrostatic discharge (ESD).

The mid plate 300 may include a material having high thermal conductivity so as to be suitable for discharging heat generated in the components disposed in the mid plate 300, for example, the first to fourth electronic chips 420, 430, 520 and 530 to the outside of the case. The mid plate 300 may include the same material as that of the case.

The first memory module 400 may be disposed in the accommodation space of the case. The first memory module 400 may be disposed between the mid plate 300 and the first case 100. In detail, the first memory module 400 may be disposed between the mid plate 300 and the lower and side wall 110 of the first case 100.

The first memory module 400 may include the first module substrate 410 and a plurality of electronic chips 420 and 430. The first module substrate 410 may have a first surface 410U and a second surface 410L, which are opposite to each other. The first module substrate 410 may have a flat plate shape extending in the first direction X and the second direction Y.

The first surface 410U of the first module substrate 410 may face the mid plate 300, and may be parallel with the base unit 310 of the mid plate 300. The first surface 410U of the first module substrate 410 may be connected to the third rib unit 331. The first conductive gasket 341 may be positioned between the first module substrate 410 and the third rib unit 331.

The second surface 410L of the first module substrate 410 may face the lower wall of the lower and side wall 110 of the first case 100, and may be parallel with the lower wall of the lower and side wall 110 of the first case 100. The second surface 410L of the first module substrate 410 may be connected to the first rib unit 140. The third conductive gasket 345 may be positioned between the first module substrate 410 and the first rib unit 140.

The second memory module 500 may include the second module substrate 510 and a plurality of electronic chips 520 and 530. The second module substrate 510 may have a third surface 510L and a fourth surface 510U, which are opposite to each other. The second module substrate 510 may have a flat plate shape extending in the first direction X and the second direction Y.

The third surface 510L of the second module substrate 510 may face the mid plate 300, and may be parallel with the base unit 310 of the mid plate 300. The third surface 510L of the second module substrate 510 may be connected to the fourth rib unit 333. The second conductive gasket 343 may be positioned between the second module substrate 510 and the fourth rib unit 333.

The fourth surface 510U of the second module substrate 510 may face the upper and side wall 210 of the second case 200, and may be parallel with the upper wall of the upper and side wall 210 of the second case 200. The fourth surface 510U of the second module substrate 510 may be connected to the second rib unit 240. The fourth conductive gasket 347 may be positioned between the second module substrate 510 and the second rib unit 240.

The first module substrate 410 and the second module substrate 510 may be printed circuit boards (PCBs). For example, the first module substrate 410 and the second module substrate 510 may be double-sided PCBs or multi-layer PCBs. For example, the first module substrate 410 and the second module substrate 510 may include a substrate layer and wiring layers. The wiring layers may be formed on upper and lower surfaces of the substrate layer and inside the substrate layer. A portion of the wiring layers may be a ground line for grounding the printed circuit board. The substrate layer may include at least one material among phenolic resin, epoxy resin and polyimide. The wiring layers may include a conductive material, for example, aluminum (Al), copper (Cu), nickel (Ni), or tungsten (W). Electronic chips and electronic components, which are packaged on the first module substrate 410 and the second module substrate 510, may be electrically connected to each other through the wiring layers of the first module substrate 410 and the second module substrate 510.

The plurality of first electronic chips 420 may be packaged on the first surface 410U of the first module substrate 410. The plurality of second electronic chips 430 may be packaged on the second surface 410L of the first module substrate 410.

The plurality of third electronic chips 520 may be packaged on the third surface 510L of the second module substrate 510. The plurality of fourth electronic chips 530 may be packaged on the fourth surface 510U of the second module substrate 510.

The plurality of first to fourth electronic chips 420, 430, 520 and 530 may include a controller chip and memory semiconductor chips. The controller chip may be configured to control the memory semiconductor chip. A control circuit portion may be embedded in the controller chip. The control circuit portion of the controller chip may control access to data stored in the memory semiconductor chip. The control circuit portion of the controller chip may control a write/read operation of a flash memory or the like in accordance with a control command from an external host. The control circuit portion of the controller chip may be configured as a separate control semiconductor chip such as an application specific integrated circuit (ASIC). The control circuit portion of the controller chip may be configured to be automatically executed by an operating system of the external host, for example, when the memory device 1000 is connected to the external host. The control circuit portion of the controller chip may provide a standard protocol such as parallel advanced technology attachment (PATA), serial advanced technology attachment (SATA), small computer system interface (SCSI) standard, or peripheral component interconnect (PCI) express (PCIe). In addition, the control circuit portion of the controller chip may perform wear leveling, garbage collection, bad block management, and/or error correction code for driving a nonvolatile memory device. In this case, the control circuit portion of the controller chip may include a script for automatic execution and an application program that may be executed in the external host.

The memory semiconductor chips may include a nonvolatile memory device and/or a volatile memory device. The nonvolatile memory device may be, for example, a flash memory, a phase-change memory (PRAM), a resistive memory (RRAM), a ferroelectric memory (FeRAM), a magnetic RAM (MRAM), or the like, but is not limited thereto. The flash memory may be, for example, a NAND flash memory. The flash memory may be, for example, a V-NAND flash memory. The nonvolatile memory device may include a single semiconductor die, or may be a device in which a plurality of semiconductor dies are stacked. The volatile memory device may be, for example, a dynamic random access memory (DRAM), a static RAM (SRAM), or the like, but is not limited thereto. The volatile memory device may provide a cache function that stores data frequently used when the external host accesses the memory device 1000, such that an access-time and data-transfer performance may be scaled to be matched with process performance of the external host connected to the memory device 1000.

The plurality of first electronic chips 420 may be physically and thermally coupled to the mid plate 300 through first thermal interface material (TIM) layers 351. In other words, the plurality of first electronic chips 420 may be in a thermal contact with the mid plate 300 by the thermal interface material. The first TIM layers 351 may be interposed between an upper surface of the first electronic chip 420 and the mid plate 300.

The plurality of second electronic chips 430 may be physically and thermally coupled to the first case 100 through second thermal interface material (TIM) layers 150. The second TIM layers 150 may be interposed between a lower surface of the second electronic chip 430 and the first case 100.

The plurality of third electronic chips 520 may be physically and thermally coupled to the mid plate 300 through third thermal interface material (TIM) layers 353. The third TIM layers 353 may be interposed between a lower surface of the third electronic chip 520 and the mid plate 300.

The plurality of fourth electronic chips 530 may be physically and thermally coupled to the second case 200 through fourth thermal interface material (TIM) layers 250.

The fourth TIM layers 250 may be interposed between an upper surface of the fourth electronic chip 530 and the second case 200.

Each of the first to fourth TIM layers 351, 150, 353 and 250 may include a resin layer and a heat dissipation filler contained in the resin layer. The first to fourth TIM layers 351, 150, 353 and 250 may be electrically non-conductors.

The screw 610 may pass through the first screw hole 130 and the second screw hole 230. The screw 610 may be coupled to the first case 100 and the second case 200. For example, the screw 610 may fix the first case 100 to the second case 200 to form the case.

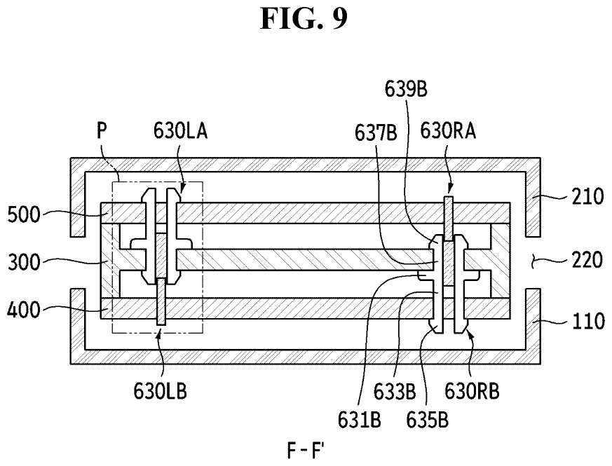

The hook 630 may connect the first memory module 400, the mid plate 300 and the second memory module 500 to one another. Hereinafter, the hook will be described in detail with reference to FIGS. 9 to 13.

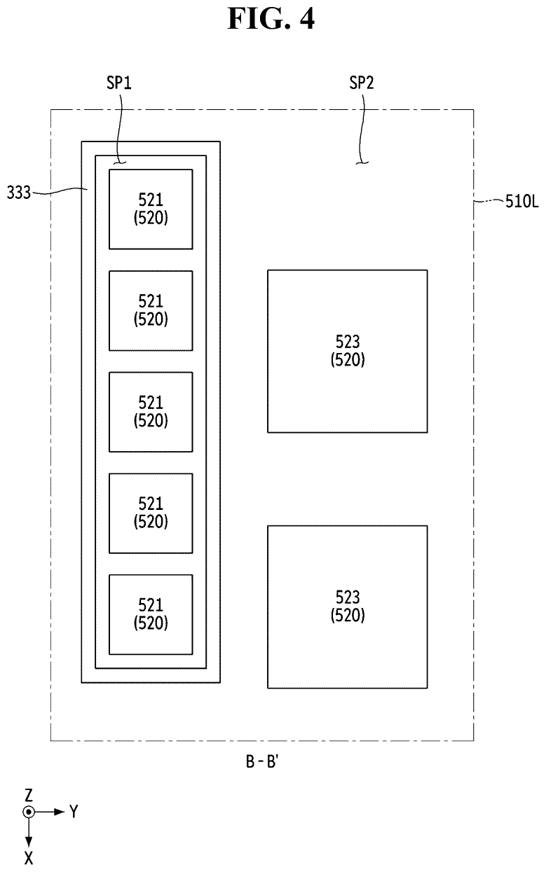

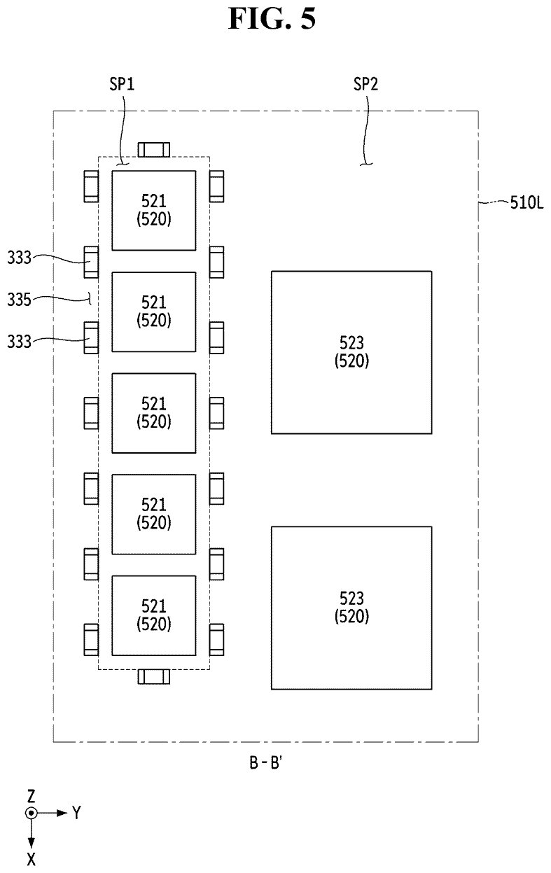

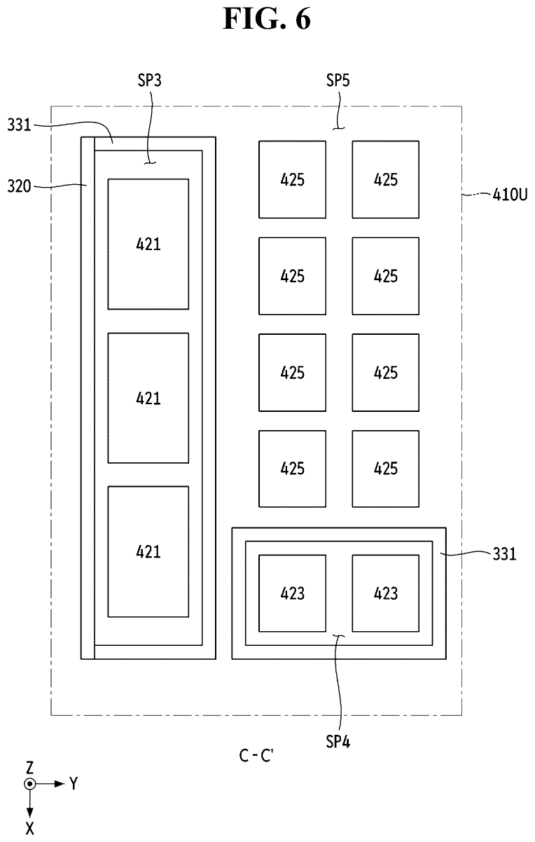

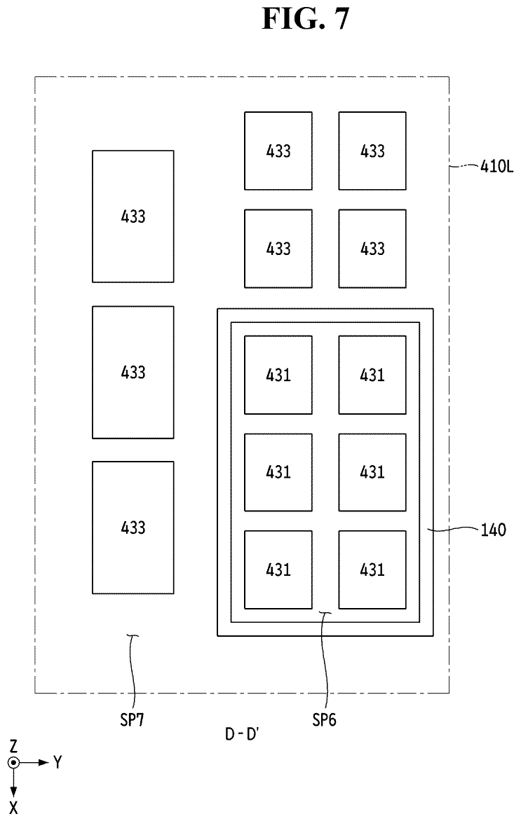

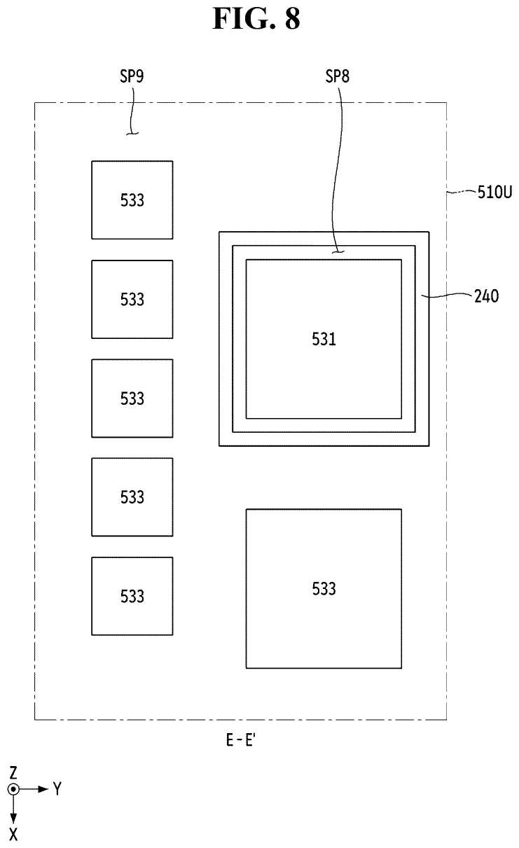

FIGS. 4 and 5 are cross-sectional views taken along line B-B′ of FIG. 3. FIG. 6 is a cross-sectional view taken along line C-C′ of FIG. 3. FIG. 7 is a cross-sectional view taken along line D-D′ of FIG. 3. FIG. 8 is a cross-sectional view taken along line E-E′ of FIG. 3.

Referring to FIGS. 3 and 4, the fourth rib unit 333 of the mid plate 300 may be disposed to surround fifth electronic chips 521 that are portions of the plurality of third electronic chips 520. The fourth rib unit 333 may define a first accommodation space SP1 for accommodating the plurality of fifth electronic chips 521 between the second module substrate 510 and the mid plate 300. The fourth rib unit 333 may define a second accommodation space SP2 for accommodating a sixth electronic chip 523 that is a portion of the plurality of third electronic chips 520. The accommodation space provided between the second module substrate 510 and the mid plate 300 may be partitioned or divided into the first accommodation space SP1 surrounded by the fourth rib unit 333 and inside the fourth rib unit 333 and the second accommodation space SP2 outside the fourth rib unit 333. Between the second module substrate 510 and the mid plate 300, the fifth electronic chips 521 may refer to chips accommodated in the first accommodation space SP1, and the sixth electronic chips 523 may refer to chips accommodated in the second accommodation space SP2.

The second conductive gasket 343 may be positioned between the fourth rib unit 333 and the second module substrate 510. Accordingly, the fourth rib unit 333 may be electrically connected to the second module substrate 510, and the first accommodation space SP1 may be shielded.

The fourth rib unit 333 of the mid plate 300 may be connected to the ground line (not shown) of the second module substrate 510. Accordingly, the mid plate 300 may prevent noise caused by electrostatic discharge (ESD).

In one or more embodiments, although the fourth rib unit 333 provides the first accommodation space SP1 surrounding the fifth electronic chip 521 packaged on the second module substrate 510, another rib unit may be further included to provide an accommodation space surrounding another electronic chip (not shown) positioned in another region of the second module substrate 510. Accordingly, at least one or more of the fourth rib unit 333 may be disposed to correspond to an element that requires blocking of electromagnetic waves. As a result, an electronic device according to an example embodiment may be effectively prevented from being damaged by any electromagnetic wave. Various modifications may be made regarding a position and/or a shape of the rib unit depending on space efficiency inside the case and reflective characteristics of any electromagnetic wave propagated into the case 100.

FIG. 5 is a cross-sectional view taken along line B-B′ of FIG. 3. In detail, FIG. 5 is a cross-sectional view illustrating a modified example of the fourth rib unit 333 shown in FIG. 4. FIG. 5 is substantially the same as the components shown in FIG. 4 except for the shape of the fourth rib unit 333. Accordingly, a detailed description of elements substantially the same as those of FIG. 4 will be omitted.

Referring to FIGS. 3 and 5, the fourth rib unit 333 of the mid plate 300 may be disposed to surround the fifth electronic chips 521 that are portions of the plurality of third electronic chips 520. The fourth rib unit 333 may define a first accommodation space SP1 for accommodating the plurality of fifth electronic chips 521 between the second module substrate 510 and the mid plate 300. The fourth rib unit 333 may define a second accommodation space SP2 for accommodating the sixth electronic chip 523 that is a portion of the plurality of fourth electronic chips 530 between the second module substrate 510 and the mid plate 300.

When viewed in a plan view, the fourth rib unit 333 may extend discontinuously along a virtual line surrounding the plurality of fifth electronic chips 521.

The fourth rib unit 333 may include a plurality of fourth rib structures 333 arranged along the virtual line surrounding the fifth electronic chips 521.

The plurality of fourth rib structures 333 may be disposed on the second module substrate 510. The second conductive gasket 343 may be positioned between the individual fourth rib structure 333 and the second module substrate 510. Accordingly, the individual fourth rib structure 333 and the second module substrate 510 may be physically and electrically connected to each other. The plurality of fourth rib structures 333 may be spaced apart from each other with a slit 335 interposed therebetween. The slit 335 may be a space or a gap formed as two adjacent fourth rib structures 333 among the plurality of fourth rib structures 333 are spaced apart from each other. The plurality of fourth rib structures 333 may be disposed through the slit 335 between the plurality of fourth rib structures 333, regardless of the plurality of third electronic chips 520.

Referring to FIGS. 3 and 6, the third rib unit 331 of the mid plate 300 may be disposed to surround seventh electronic chips 421 and eighth electronic chips 423, which are portions of the plurality of first electronic chips 420. The third rib unit 331, along with the connection unit 320, may define a third accommodation space SP3 for accommodating the plurality of seventh electronic chips 421 between the first module substrate 410 and the mid plate 300. The third rib unit 331 may define a fourth accommodation space SP4 for accommodating the plurality of eighth electronic chips 423. The third rib unit 331 may define a fifth accommodation space SP5 for accommodating a ninth electronic chip 425 that is a portion of the plurality of third electronic chips 520. The accommodation space provided between the first module substrate 410 and the mid plate 300 may be partitioned or divided into the third and fourth accommodation spaces SP3 and SP4 surrounded by the third rib unit 331 and inside the third rib unit 331 and the fifth accommodation space SP5 outside the third rib unit 331.

The first conductive gasket 341 may be positioned between the third rib unit 331 and the first module substrate 410. Accordingly, the third rib unit 331 may be electrically connected to the first module substrate 410, and the third and fourth accommodation spaces SP3 and SP4 may be shielded.

The third rib unit 331 of the mid plate 300 may be connected to the ground line (not shown) of the first module substrate 410. Accordingly, the mid plate 300 may prevent noise caused by electrostatic discharge (ESD).

In one or more embodiments, the third rib unit 331 may extend from the base unit 310 in the third direction Z, and may be in a direction opposite to an extending direction of the fourth rib unit 333. The third rib unit 331 of the mid plate 300 may include a plurality of third rib structures arranged along a virtual line surrounding the seventh or eighth electronic chips 421 or 423. The plurality of third rib structures may be spaced apart from each other with a slit interposed therebetween. The third rib unit 331 of the mid plate 300 may be similar to the fourth rib unit 333 described with reference to FIGS. 3 to 5.

Referring to FIGS. 3 and 7, the first rib unit 140 of the first case 100 may be disposed to surround a tenth electronic chip 431, which is a portion of the plurality of second electronic chips 430. The first rib unit 140 may define a sixth accommodation space SP6 for accommodating a plurality of tenth electronic chips 431 between the first module substrate 410 and the first case 100. The first rib unit 140 may define a seventh accommodation space SP7 for accommodating an eleventh electronic chips 433, which is a portion of the plurality of second electronic chips 430, between the first module substrate 410 and the first case 100. The third rib unit 331 may define the sixth accommodation space SP6 for accommodating a ninth electronic chip 425 that is a portion of the plurality of third electronic chips 520. The accommodation space provided between the first module substrate 410 and the first case 100 may be partitioned or divided into the sixth accommodation space SP6 surrounded by the first rib unit 140 and inside the first rib unit 140 and the seventh accommodation space SP7 outside the first rib unit 140.

The third conductive gasket 345 may be positioned between the first rib unit 140 and the first module substrate 410. The first rib unit 140 of the first case 100 may be connected to the ground line (not shown) of the first module substrate 410. Accordingly, the first rib unit 140 may be electrically connected to the first module substrate 410, and the sixth accommodation space SP6 may be shielded. Accordingly, the memory device may prevent noise caused by electrostatic discharge (ESD).

In one or more embodiments, the first rib unit 140 may include a plurality of first rib structures arranged along a virtual line surrounding the tenth electronic chips 431.

The plurality of first rib structures may be spaced apart from each other with a slit interposed therebetween. The first rib unit 140 of the first case 100 may be similar to the rib unit of the mid plate 300.

Referring to FIGS. 3 and 8, the second rib unit 240 of the second case 200 may be disposed to surround a twelfth electronic chip 531, which is a portion of the plurality of fourth electronic chips 530. The second rib unit 240 may define an eighth accommodation space SP8 for accommodating the twelfth electronic chip 531 between the second module substrate 510 and the second case 200. The second rib unit 240 may define a ninth accommodation space SP9 for accommodating thirteenth electronic chips 533, which are portions of the plurality of fourth electronic chips 530, between the second module substrate 510 and the second case 200. The second rib unit 240 may define the eighth accommodation space SP8 for accommodating the twelfth electronic chip 531 that is a portion of the plurality of fourth electronic chips 530. The accommodation space provided between the second module substrate 510 and the second case 200 may be partitioned or divided into the eighth accommodation space SP8 surrounded by the second rib unit 240 and inside the second rib unit 240 and the ninth accommodation space SP9 outside the second rib unit 240.

The fourth conductive gasket 347 may be positioned between the second rib unit 240 and the second case 200. The second rib unit 240 of the second case 200 may be connected to the ground line (not shown) of the second module substrate 510. Accordingly, the second rib unit 240 may be electrically connected to the second module substrate 510, and the eighth accommodation space SP8 may be shielded. Accordingly, the memory device may prevent noise caused by electrostatic discharge (ESD).

In one or more embodiments, the second rib unit 240 may include a plurality of second rib structures arranged along a virtual line surrounding the twelfth electronic chips 531. The plurality of second rib structures may be spaced apart from each other with a slit interposed therebetween. The second rib unit 240 of the second case 200 may be similar to the rib unit between the mid plate 300 and the first case 100.

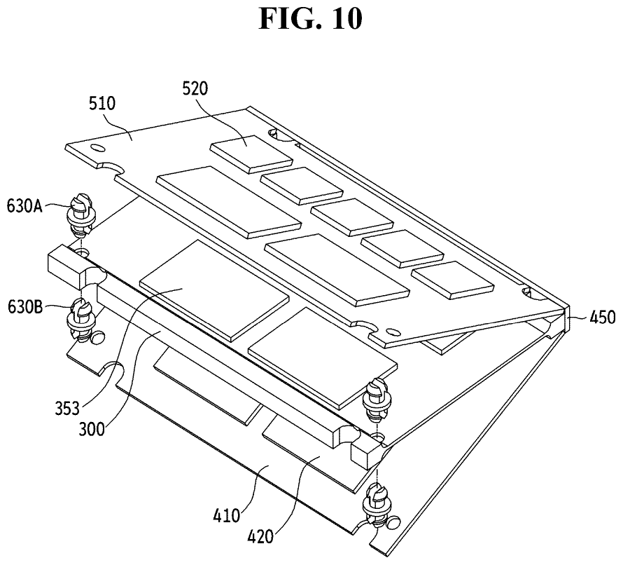

FIG. 9 is a cross-sectional view taken along line F-F′ of FIG. 2. FIG. 10 is a partial perspective view illustrating a hook included in a memory device according to one or more embodiments of the disclosure.

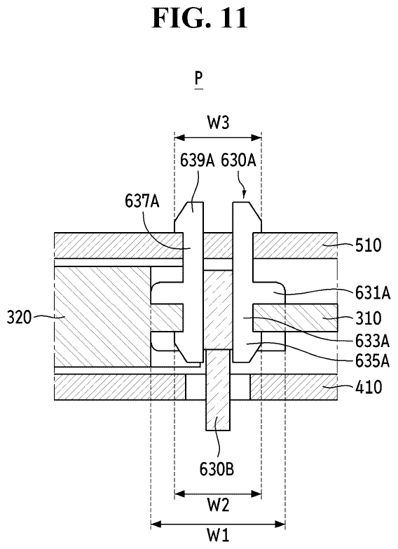

FIG. 11 is an enlarged view of a region P of FIG. 9. The following description will be based on differences from those described with reference to FIGS. 1 to 8.

Referring to FIGS. 9 and 10, a first hook 630 may include a lower hook 630B and an upper hook 630A. The lower hook 630B may be connected to the first memory module 400 and the mid plate 300. The upper hook 630A may be connected to the second memory module 500 and the mid plate 300.

In one or more embodiments, there may be two lower hooks 630LB and 630RB of the memory device 1000. For example, the lower hooks 630LB and 630RB may be arranged along the first direction X. In one or more embodiments, there may be two upper hooks 630LA and 630RA of the memory device 1000. For example, the upper hooks 630LA and 630RA may be arranged along the first direction X.

The lower hook 630B and the upper hook 630A may be coupled to each other in the third direction Z. For example, the upper hook 630A may have a shape in which the lower hook 630B rotates 90° in the third direction Z. In one or more embodiments, the lower hook 630B and the upper hook 630A may have the same shape.

As the lower hook 630B and the upper hook 630A are coupled to each other, the first memory module 400, the mid plate 300 and the second memory module 500 may be bound to one another.

Referring to FIGS. 9 to 11, the upper hook 630A may include a first body portion 631A, a first extension portion 633A, a second extension portion 637A, a first protrusion portion 635A, and a second protrusion portion 639A. The lower hook 630B may include a second body portion 631B, a third extension portion 633B, a fourth extension portion 637B, a third protrusion portion 635B, and a fourth protrusion portion 639B.

The first body portion 631A may have a disk shape extending in the first direction X and the second direction Y. The first body portion 631A may include a hole that is empty in a center thereof. The third extension portion 633B of the lower hook 630B may pass through the hole of the first body portion 631A. The first body portion 631A may be positioned on the mid plate 300. A portion at which the first body portion 631A of the upper hook 630A is connected with the mid plate 300 may have a first width W1.

The first extension portion 633A and the second extension portion 637A may extend from the first body portion 631A in the third direction Z. The first extension portion 633A and the second extension portion 637A may be positioned in the third direction Z to be opposite to each other based on the first body portion 631A.

The first extension portion 633A may include the first protrusion portion 635A, which protrudes from one end of the first extension portion 633A in the first or second direction. The first protrusion portion 635A may be positioned on the mid plate 300. A portion at which the first protrusion portion 635A of the upper hook 630A is connected to the mid plate 300 may have a second width W2.

The second extension portion 637A may include the second protrusion portion 639A, which protrudes from one end of the second extension portion 637A in the first or second direction. The second protrusion portion 639A may be positioned on the fourth surface 510U of the second module substrate 510. A portion at which the second protrusion portion 639A of the upper hook 630A is connected to the second module substrate 510 may have a third width W3.

The second body portion 631B may have a disk shape extending in the first direction X and the second direction Y. The second body portion 631B may include a hole that is empty in a center thereof. The first extension portion 633A of the upper hook 630A may pass through the hole of the second body portion 631B.

The third extension portion 633B and the fourth extension portion 637B may extend from the second body portion 631B in the third direction Z. The third extension portion 633B and the fourth extension portion 637B may be positioned in the third direction Z to be opposite to each other based on the second body portion 631B.

The third extension portion 633B may include a third protrusion portion 635B, which protrudes from one end of the third extension portion 633B in the first or second direction. The third protrusion portion 635B may be positioned on the second surface 410L of the first module substrate 410.

The fourth extension portion 637B may include a fourth protrusion portion 639B, which protrudes from one end of the fourth extension portion 637B in the first or second direction. The fourth protrusion portion 639B may be positioned on the mid plate 300.

In one or more embodiments, the first width W1 may be greater than the second width W2 or the third width W3. For example, the first width W1 of the portion at which the first body portion 631A is connected to the mid plate 300 may be greater than the second width W2 of the portion at which the first protrusion portion 635A is connected to the mid plate 300 or the third width W3 of the portion at which the second protrusion portion 639A of the upper hook 630A is connected to the second module substrate 510. In one or more embodiments, the lower hook 630B and the upper hook 630A may have the same shape. Accordingly, a region in which the first memory module 400 and the second memory module 500 are coupled to the hook may be minimized. As a result, a region in which a plurality of electronic chips are packaged in the first memory module 400 and the second memory module 500 may be maximized.

In one or more embodiments, the first module substrate 410 and the second module substrate 510 may be connected to one edge by a connection member 450 such that two pairs of hooks are positioned at the edge, but a position and a number of hooks are not limited to those shown.

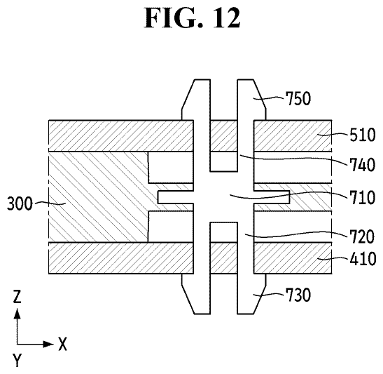

FIG. 12 is a cross-sectional view illustrating a first modified example of the hook shown in FIG. 11.

Referring to FIG. 12, a second hook may be coupled to the mid plate 300. The second hook may include a third body portion 710, a fifth extension portion 720, a sixth extension portion 740, a fifth protrusion portion 730, and a sixth protrusion portion 750.

The third body portion 710 may have a disk shape extending in the first direction X and the second direction Y. The third body portion 710 may be positioned in the base unit 310 of the mid plate 300.

The fifth extension portion 720 and the sixth extension portion 740 may extend from the third body portion 710 in the third direction Z. The fifth extension portion 720 and the sixth extension portion 740 may be positioned in the third direction Z to be opposite to each other based on the third body portion 710.

The fifth extension portion 720 may include the fifth protrusion portion 730 that protrudes from one end of the fifth extension portion 720 in the first or second direction. The fifth protrusion portion 730 may be positioned on the second surface 410L of the first module substrate 410.

The sixth extension portion 740 may include the sixth protrusion portion 750 that protrudes from one end of the sixth extension portion 740 in the first or second direction. The sixth protrusion portion 750 may be positioned on the fourth surface 510U of the second module substrate 510.

As the fifth protrusion portion 730 and the sixth protrusion portion 750 of the second hook are coupled to the first memory module 400 and the second memory module 500, respectively, the first memory module 400, the mid plate 300 and the second memory module 500 may be bound to one another. Accordingly, a region in which the first memory module 400 and the second memory module 500 are coupled to the second hook may be minimized. As a result, the region in which a plurality of electronic chips are packaged in the first memory module 400 and the second memory module 500 may be maximized.

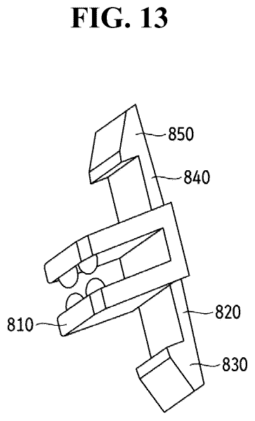

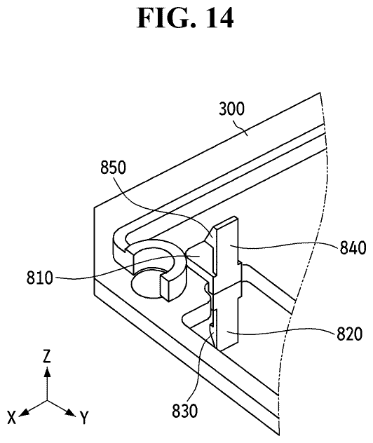

FIG. 13 is a perspective view illustrating a second modified example of the hook shown in FIG. 11. FIG. 14 is a perspective view illustrating a coupling relationship between a mid plate and the second modified example of the hook shown in FIG. 13.

Referring to FIGS. 13 and 14, a third hook may include a fourth body portion 810, a seventh extension portion 820, an eighth extension portion 840, a seventh protrusion portion 830, and an eighth protrusion portion 850.

The fourth body portion 810 may include two plates extending in the first direction X or the second direction Y. The two plates constituting the fourth body portion 810 may be parallel with each other, and may face each other in the third direction Z. The two plates constituting the fourth body portion 810 may be positioned on the mid plate 300.

Although shown in a plate shape, the fourth body portion may have various shapes, and the disclosure is not limited thereto.

The seventh extension portion 820 and the eighth extension portion 840 may extend from the fourth body portion 810 in the third direction Z. The seventh extension portion 820 and the eighth extension portion 840 may be positioned in the third direction Z to be opposite to each other based on the fourth body portion 810.

The seventh extension portion 820 may include the seventh protrusion portion 830 that protrudes from one end of the seventh extension portion 820 in the first or second direction. The seventh protrusion portion 830 may be positioned on the second surface 410L of the first module substrate 410.

The eighth extension portion 840 may include the eighth protrusion portion 850 that protrudes from one end of the eighth extension portion 840 in the first or second direction. The eighth protrusion portion 850 may be positioned on the fourth surface 510U of the second module substrate 510.

As the seventh protrusion 830 and the eighth protrusion 850 of the third hook are coupled to the first memory module 400 and the second memory module 500, respectively, the first memory module 400, the mid plate 300 and the second memory module 500 may be bound to one another. Accordingly, a region in which the first memory module 400 and the second memory module 500 are coupled to the third hook may be minimized. As a result, the region in which a plurality of electronic chips are packaged in the first memory module 400 and the second memory module 500 may be maximized.

Although the shape of the hook in the memory device according to one or more embodiments is shown using FIGS. 9 to 14, the disclosure is not limited thereto.

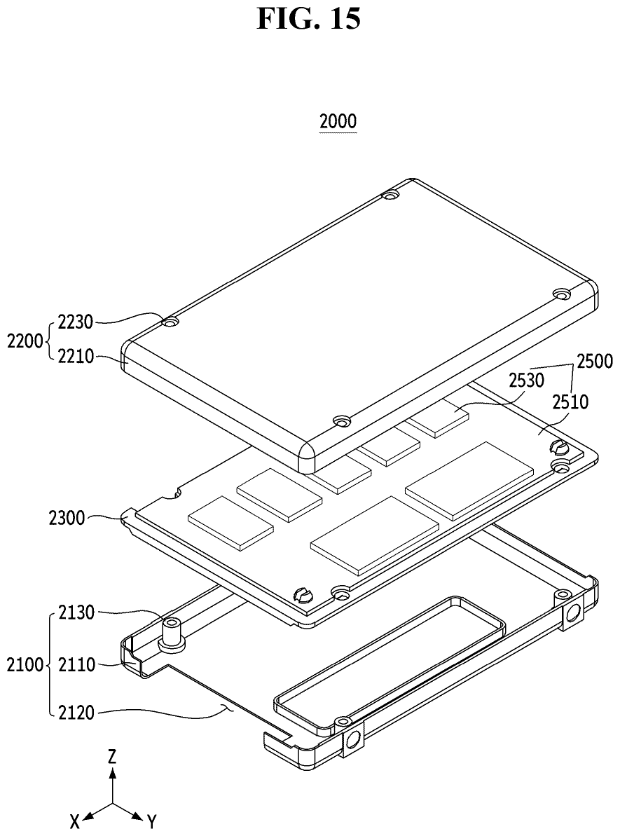

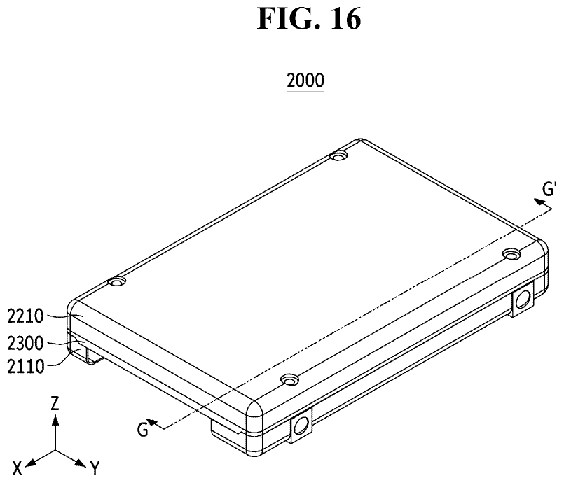

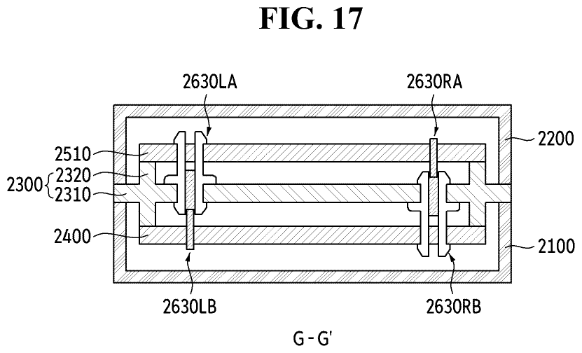

FIG. 15 is an exploded perspective view of a memory device according to one or more embodiments of the disclosure. FIG. 16 is a perspective view of a memory device according to one or more embodiments of the disclosure. FIG. 17 is a cross-sectional view taken along line G-G′ of FIG. 15. The memory device shown in FIGS. 15 to 17 is substantially the same as the semiconductor device described with reference to FIG. 1 except for the case. Accordingly, repeated descriptions of the same elements will be omitted.

Referring to FIGS. 15 to 17, a memory device 2000 includes a case, a mid plate 2300, a first memory module 2400, and a second memory module 2500.

The case may provide an external appearance of the memory device 2000. The case may include a first case 2100 and a second case 2200, which are detachably coupled to each other. The first case 2100 may include a lower and side wall 2110 of the case, a first hole 2120, and a first screw hole 2130. A sidewall of the first case 2100 may have a plate shape having no hole. The second case 2200 may include an upper and side wall 2210 of the case, and a second screw hole 2230.

The mid plate 2300 may be positioned inside the case. The mid plate 2300 may be positioned on an accommodation space of the case. The mid plate 2300 may include a base unit 2310, a connection unit 2320, a third rib unit (not shown), and a fourth rib unit (not shown).

The base unit 2310 may have a flat plate shape extending in the first direction X and the second direction Y. The base unit 2310 may be connected to portions of the first case 2100 and the second case 2200. A portion of the base unit 2310 may be exposed to an outside of the case. For example, an edge of the base unit 2310 may be positioned between the first case 2100 and the second case 2200, and may be exposed to the outside of the case. Accordingly, heat generated inside the case may be easily dissipated through the mid plate 2300.

The first memory module 2400 may include a first module substrate and a first electronic chip. The second memory module 2500 may include a second module substrate 2510 and a second electronic chip 2530. The memory device 2000 may further include two upper hooks 2630LA and 2630RA and two lower hooks 1630LB and 2630RB, which may be the same or similar to the upper hooks 630LA and 630RA and the lower hooks 630LB and 630RB of the memory device 1000 shown in FIG. 9.

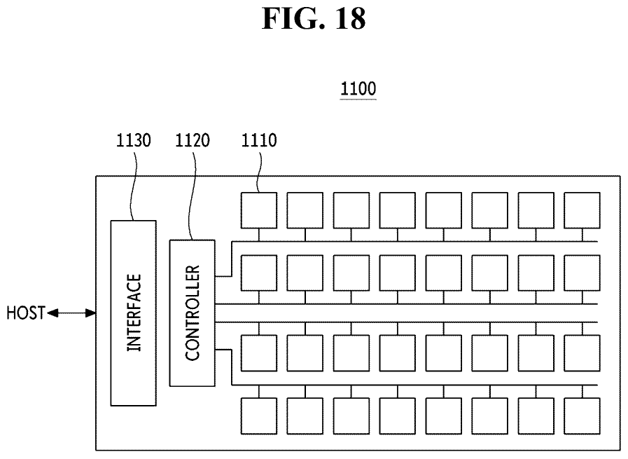

FIG. 18 is a schematic view of a memory device according to one or more embodiments of the disclosure.

A solid state drive device 1100 may include a plurality of nonvolatile memories 1110 and a controller 1120. The nonvolatile memory 1110 may have nonvolatile characteristics capable of storing data and maintaining the stored data even when power supply is stopped. The solid state drive device 1100 may be one of the memory devices 1000 and 2000.

The controller 1120 may read data stored in the nonvolatile memory 1110 in response to a read/write request from a host HOST, or may store data of the nonvolatile memory 1110. An interface 1130 may transmit command and address signals to the host HOST or receive these signals from the host HOST, and may again transmit the command and address signals to the nonvolatile memory 1110 through the controller 1120 or receive these signals from the nonvolatile memory 1110.

The solid state drive device 1110 may further include an active or passive element such as a resistor, a capacitor, an inductance, a switch, a temperature sensor, a DC-DC converter, a quartz for clock generation or a voltage regulator.

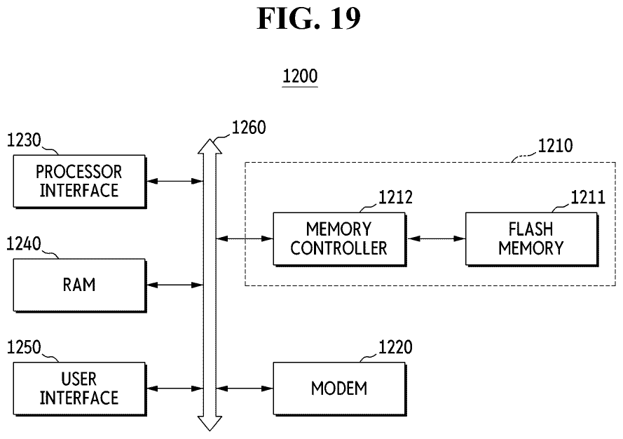

FIG. 19 is a block diagram of a system including a memory device according to one or more embodiments of the disclosure.

A system 1200 may include a processor 1230, such as a central processing unit (CPU) configured to perform communication through a common bus 1260, a random access memory 1240, a user interface 1250, and a modem 1220. The respective elements may transmit signals to a memory device 1210 through the common bus 1260 and receive the signals from the memory device 1210. The memory device 1210 may include a flash memory 1211 and a memory controller 1212. The flash memory 1211 may store data, and may have nonvolatile characteristics capable of maintaining stored data even when power supply is stopped. The memory device 1210 may be one of the aforementioned memory devices 1000 and 2000.

In concluding the detailed description, those skilled in the art will appreciate that many variations and modifications may be made to the example embodiments without substantially departing from the principles of the disclosure. Therefore, the disclosed embodiments of the disclosure are used in a generic and descriptive sense only and not for purposes of limitation.

1. A memory device comprising:
a first case;
a second case coupled to the first case;
a mid plate in an inner space between the first case and the second case, the mid plate extending in a first direction;
a first memory module between the first case and the mid plate, the first memory module comprising a first module substrate and at least one first electronic chip on the first module substrate; and
a second memory module between the second case and the mid plate, the second memory module comprising a second module substrate and at least one second electronic chip on the second module substrate,
wherein the mid plate comprises a base unit extending in the first direction, a first rib structure extending from the base unit in a second direction crossing the first direction to connect the mid plate and the first module substrate, and a second rib structure spaced apart from the first rib structure in the first direction and extending in the second direction to connect the mid plate and the first module substrate.

2. The memory device of claim 1, wherein the first rib structure, the at least one first electronic chip, and the second rib structure are sequentially spaced apart from one another along the first direction.

3. The memory device of claim 1, wherein the mid plate further comprises a third rib structure spaced apart from the first rib structure and the second rib structure in the first direction and extending in the second direction to connect the mid plate and the first module substrate.

4. The memory device of claim 1, wherein the mid plate further comprises a third rib structure extending in the second direction to connect the mid plate and the second module substrate, and a fourth rib structure spaced apart from the third rib structure in the first direction and extending in the second direction to connect the mid plate and the second module substrate.

5. The memory device of claim 1, wherein the at least one first electronic chip is in a thermal contact with the mid plate by a thermal interface material.

6. The memory device of claim 1, wherein the first rib structure and the second rib structure are connected to the first module substrate by at least one conductive gasket.

7. The memory device of claim 1, further comprising a hook connecting the first module substrate, the mid plate, and the second module substrate.

8. The memory device of claim 7, wherein the hook and the first module substrate are connected in a first connection region, the hook and the second module substrate are connected in a second connection region, the hook and the mid plate are connected in a third connection region, and an area of the first connection region or the second connection region is smaller than an area of the third connection region.

9. The memory device of claim 8, wherein the hook comprises a first hook connected to the first module substrate and the mid plate and a second hook connected to the second module substrate and the mid plate.

10. The memory device of claim 9, wherein the first hook is coupled to the second hook in the second direction.

11. A memory device comprising:
a first case;
a second case coupled to the first case;
a mid plate in an inner space between the first case and the second case, the mid plate extending in a first direction;
a first memory module between the first case and the mid plate, the first memory module including a first module substrate and at least one first electronic chip on the first module substrate; and
a second memory module between the second case and the mid plate, the second memory module including a second module substrate and at least one second electronic chip on the second module substrate,
wherein the mid plate comprises a base unit and a first rib structure on the base unit, surrounding the at least one first electronic chip and electrically connecting the mid plate and the first module substrate.

12. The memory device of claim 11, wherein the first rib structure is continuously connected to surround the at least one first electronic chip.

13. The memory device of claim 11, wherein the first rib structure comprises a plurality of first unit rib structures, and the plurality of first unit rib structures are spaced apart from each other with a slit interposed therebetween.

14. The memory device of claim 11, wherein the mid plate further comprises a second rib structure on the base unit, surrounding the at least one second electronic chip and electrically connecting the mid plate and the second module substrate.

15. The memory device of claim 11, wherein the first rib structure is electrically connected to the first module substrate by at least one conductive gasket.

16. The memory device of claim 11, further comprising a hook connecting the first module substrate, the mid plate and the second module substrate.

17. (canceled)

18. A memory device comprising:
a first case;
a second case coupled to the first case;
a mid plate in an inner space between the first case and the second case, the mid plate extending in a first direction;
a first module substrate between the first case and the mid plate, the first module substrate including a first surface facing the first case and a second surface facing the mid plate;
at least one first electronic chip on the first surface of the first module substrate;
at least one second electronic chip on the second surface of the first module substrate;
a second module substrate between the second case and the mid plate, the second module substrate including a third surface facing the second case and a fourth surface facing the mid plate;
at least one third electronic chip on the third surface of the second module substrate; and
at least one fourth electronic chip on the fourth surface of the second module substrate,
wherein the mid plate comprises a base unit, a first rib structure on the base unit, surrounding the at least one second electronic chip and electrically connecting the mid plate and the second surface of the first module substrate, and a second rib structure on the base unit, surrounding the at least one fourth electronic chip and electrically connecting the mid plate and the fourth surface of the second module substrate.

19. The memory device of claim 18, wherein the first case comprises a third rib structure extending from the first case in a second direction crossing the first direction to electrically connect the first case and the first surface of the first module substrate, and
wherein the second case comprises a fourth rib structure extending from the second case in the second direction to electrically connect the second case and the third surface of the second module substrate.

20. The memory device of claim 18, wherein the first rib structure and the second rib structure are electrically connected to the first module substrate or the second module substrate by at least one conductive gasket.

21. The memory device of claim 18, wherein the at least one second electronic chip and the at least one fourth electronic chip are in contact with the mid plate through a thermal interface material,
wherein the at least one first electronic chip is in contact with the first case through the thermal interface material, and
wherein the at least one third electronic chip is in contact with the second case through the thermal interface material.

22. (canceled)
